(19) United States
(12) Patent Application Publication
(10) Pub. No.: US 2009/0189282 A1
(43) Pub. Date: Jul. 30, 2009

(54) Semiconductor device

(75) Inventors: Yoshihisa Takada, Kyoto (JP); Satoshi Kageyama, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/318,862

(22) Filed: Jan. 9, 2009

(30) Foreign Application Priority Data
Jan. 10, 2008 (JP) 2008-3435
Jan. 8, 2009 (JP) 2009-2808

(51) Int. Cl. H01L 23/532

(52) U.S. Cl. 257/751; 257/E23.161

(57) ABSTRACT

A semiconductor device according to the present invention includes: a low dielectric layer made of a low dielectric material; a high dielectric layer formed on the low dielectric layer and made of a high dielectric material having a higher dielectric constant than the low dielectric material; a protective layer formed on the high dielectric layer and made of an insulating material differing from the low dielectric material and the high dielectric material; a groove formed by digging in from an upper surface of the protective layer to the low dielectric layer; a barrier film coated onto a bottom surface and side surfaces of the groove and made of a material having a barrier property with respect to diffusion of Cu; and a wiring formed on the barrier film, made of a metal material having Cu as a main component, and completely filling the groove.

### BACKGROUND OF THE INVENTION

1. Field of the Invention

The present invention relates to a semiconductor device including a Cu (copper) wiring.

2. Description of Related Art

With the making of semiconductor devices more highly integrated, the making of wiring even finer is being demanded. To suppress increase in wiring resistance due to wiring being made finer, use of Cu (copper), which has a higher conductivity than Al (aluminum), as a wiring material is being examined.

FIG. 3 is a schematic sectional view of a portion of a top layer of a conventional semiconductor device and shows a state in a middle of forming of a Cu wiring. FIG. 4 is a plan view of a state before the semiconductor device shown in FIG. 3 is cut into an individual piece. FIG. 5 is a schematic plan view of a portion of a peripheral edge portion of the semiconductor device in the state shown in FIG. 4.

The semiconductor device 101 is manufactured with a semiconductor substrate, making up a base of the semiconductor device, being in a state of a semiconductor wafer (hereinafter, referred to simply as “wafer”) W. After the Cu wiring etc., are formed on the wafer W, the wafer W is cut along a scribe line to obtain the semiconductor device 101 that has been cut out as an individual piece.

On the wafer W (see FIG. 4), a first interlayer insulating film 102 made of an SiOC (silicon oxide with carbon added), an etching stopper film 103 made of an SiCO (silicon carbide with oxygen added), a second interlayer insulating film 104 made of an SiOC and a protective layer 105 made of SiO₂ (silicon oxide) are laminated in that order from the wafer W side.

After forming the protective layer 105, rinsing of a rear surface of the wafer W is performed. During rinsing, a rinsing liquid supplied to the rear surface of the wafer W flows around to the peripheral edge portion P (see FIG. 4) of a top surface of the wafer W and the protective layer 105 is removed from the peripheral edge portion P. Thus, at the peripheral edge portion P of the wafer W, the second interlayer insulating film 104 is exposed. The peripheral edge portion P has a width D, for example, of approximately 3 mm.

In forming the Cu wiring, a wiring groove 107 is formed by digging in from an upper surface of the protective layer 105 to the first interlayer insulating film 102.

Thereafter, a barrier film 108 made of Ta (tantalum) is formed on the protective layer 105 including an inner surface of the wiring groove 107. At the peripheral edge portion P of the wafer W, the barrier film 108 contacts a portion of the second interlayer film 104 exposed from the protective layer 105.

A plating layer 109 made of Cu is then formed on the barrier film 108. The plating layer 109 is formed to a thickness of completely filling the wiring groove 107. The plating layer 109 is then removed from the peripheral edge portion P of the wafer W. Remaining of the plating layer 109 at the peripheral edge portion P of the wafer W after polishing of the plating layer 109 to be described below can thereby be prevented.

Thereafter, the plating layer 109 and the barrier film 108 are polished by a CMP. The polishing of the plating layer 109 and the barrier film 108 is continued until portions of the plating layer 109 and the barrier film 108 outside the wiring groove 107 are removed and a top surface of the protective layer 105 is exposed. Consequently, the Cu wiring (not shown) embedded in the wiring groove 107 via the barrier film 108 is obtained.

With the semiconductor device 101, SiOC, which is a low dielectric material, is used as the material of the second interlayer insulating film 104 to reduce parasitic capacitance. However, SiOC is low in adhesion with Ta, which is the material of the barrier film 108. Thus, during the polishing of the plating layer 109 and the barrier film 108, the barrier film 108 may become peeled from the second interlayer insulating film 104 at the peripheral edge portion P of the wafer W as shown in FIG. 3. When the peeled portion of the barrier film 108 separates from a remaining portion and becomes a peeled piece of the barrier film 108, the peeled piece of the barrier film 108 may enter between a polishing pad (not shown) used in the CMP and the wafer W and a scratch due to the peeled piece may form on a top surface of the Cu wiring.

In FIG. 5, portions at which peeling of the barrier film 108 has occurred are illustrated by cross hatching.

### SUMMARY OF THE INVENTION

An object of the present invention is to provide a semiconductor device with which forming of a peeled piece of a barrier film in a manufacturing process can be prevented.

A semiconductor device according to one aspect of the present invention includes: a low dielectric layer made of a low dielectric material; a high dielectric layer formed on the low dielectric layer and made of a high dielectric material having a higher dielectric constant than the low dielectric material; a protective layer formed on the high dielectric layer and made of an insulating material differing from the low dielectric material and the high dielectric material; a groove formed by digging in from an upper surface of the protective layer to the low dielectric layer; a barrier film coated onto a bottom surface and side surfaces of the groove and made of a material having a barrier property with respect to diffusion of Cu; and a wiring formed on the barrier film, made of a metal material having Cu as a main component, and completely filling the groove.

With the present semiconductor device, the high dielectric layer made of the high dielectric material having the relatively high dielectric constant is formed on the low dielectric layer made of the low dielectric material having the relatively low dielectric constant. The protective layer made of the insulating material that differs from the low dielectric material and the high dielectric material is formed on the high dielectric layer. That is, the high dielectric layer is interposed between the low dielectric layer and the protective layer. The groove dug in from the upper surface of the protective layer to the low dielectric layer is formed in the low dielectric layer, the high dielectric layer, and the protective layer. The barrier film made of the material having the barrier property with respect to the diffusion of Cu is formed on the bottom surface and the side surfaces of the groove. The wiring made of the metal material having Cu as the main component and completely filling the groove is formed on the barrier film.

The semiconductor device is obtained, for example, by the wiring etc., being formed on a wafer and the wafer being diced thereafter. Because the high dielectric layer is interposed between the low dielectric layer and the protective layer, even if the barrier film is formed on an entire surface of the wafer after removal of the protective layer from a peripheral edge portion of the wafer, the barrier film contacts the high dielectric layer, which exhibits high adhesion with the barrier film, at the peripheral edge portion of the wafer. Thus, even if the material of the wiring is deposited on the barrier film and the deposited material is polished by a CMP, forming of a peeled piece of the barrier film during the polishing can be prevented. Consequently, forming of a scratch on a top surface of the wiring due to a peeled piece of the barrier film can be prevented.

Preferably, the high dielectric layer has a thickness of not less than 5 nm and not more than 30 nm. By the thickness of the high dielectric layer being not less than 5 nm, the high dielectric layer can be formed to a uniform film thickness as a whole. Further, by the thickness being not more than 30 nm, increase in parasitic capacitance in the semiconductor device can be suppressed.

When an SiOC is used as the high dielectric material and a Ta-based material is used as the material of the barrier film, the SiOC that is the high dielectric material preferably has a dielectric constant of not less than 3. The high dielectric layer made of the SiOC having such a dielectric constant can exhibit good adhesion with the barrier film made of the Ta-based material.

The low dielectric layer and the high dielectric layer may be formed using materials of the same type that differ in dielectric constant. For example, SiOCs may be used as the low dielectric material and the high dielectric material. In this case, it suffices that an SiOC that is the high dielectric material has a dielectric constant enabling good adhesion with the barrier film to be exhibited and an SiOC that is the low dielectric material has a dielectric constant lower than that of the SiOC that is the material of the high dielectric layer.

In the case where the barrier film is made of Ta, an SiOC having a dielectric constant of 3.2 is used as the high dielectric material, and an SiOC having a dielectric constant of 2.8 is used as the low dielectric material. The high dielectric layer and the barrier film can thereby be adhered well while exhibiting integrity of the high dielectric layer and the low dielectric layer.

The foregoing and other objects, features and effects of the present invention will become more apparent from the following detailed description of the embodiments with reference to the attached drawings.

### BRIEF DESCRIPTION OF THE DRAWINGS

FIG. 1 is a schematic sectional view of a structure of a semiconductor device according to an embodiment of the present invention.

FIG. 2A is a schematic sectional view for describing a method for manufacturing the semiconductor device of FIG. 1.

FIG. 2B is a schematic sectional view of a step subsequent to that of FIG. 2A.

FIG. 2C is a schematic sectional view of a step subsequent to that of FIG. 2B.

FIG. 2D is a schematic sectional view of a step subsequent to that of FIG. 2C.

FIG. 2E is a schematic sectional view of a step subsequent to that of FIG. 2D.

FIG. 3 is a schematic sectional view of a portion of a top layer of a conventional semiconductor device.

FIG. 4 is a plan view of a state before the semiconductor device shown in FIG. 3 is cut into an individual piece.

FIG. 5 is a schematic plan view of a portion of a peripheral edge portion of the semiconductor device in the state shown in FIG. 4.

### DETAILED DESCRIPTION OF THE PREFERRED EMBODIMENTS

An embodiment of the present invention shall now be described in detail with reference to the attached drawings.

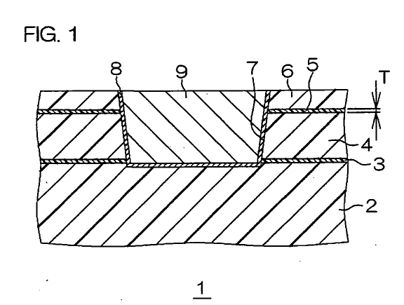

FIG. 1 is a schematic sectional view of a structure of a semiconductor device according to the embodiment of the present invention.

The semiconductor device 1 includes an unillustrated semiconductor substrate (for example, a silicon substrate) that forms a base thereof. On the semiconductor substrate, an interlayer insulating film 2 made of an SiOC with a dielectric constant of 2.8 (hereinafter, referred to simply as “SiOC (2.8)”), an etching stopper film 3 made of an SiCO, a low dielectric layer 4 made of the SiOC (2.8), a high dielectric layer 5 made of an SiOC with a dielectric constant of 3.2 (hereinafter, referred to simply as “SiOC (3.2)”), and a protective layer 6 made of SiO₂ are laminated in that order from the semiconductor substrate side.

The high dielectric layer 5 is formed to a predetermined film thickness T. In the present embodiment, the film thickness T is set, for example, in a range of not less than 5 nm and not more than 30 nm.

A wiring groove 7, dug in from an upper surface of the protective layer 6 to the interlayer insulating film 2, is formed in the etching stopper film 3, the low dielectric layer 4, the high dielectric layer 5, and the protective layer 6. A barrier film 8 made of Ta that has a barrier property with respect to diffusion of Cu is coated onto side surfaces and a bottom surface of the wiring groove 7. A Cu wring 9 made of Cu and completely filling the wiring groove 7 is formed on the barrier film 8. An upper surface of the Cu wiring 9 is substantially flush with an upper surface of the protective layer 6.

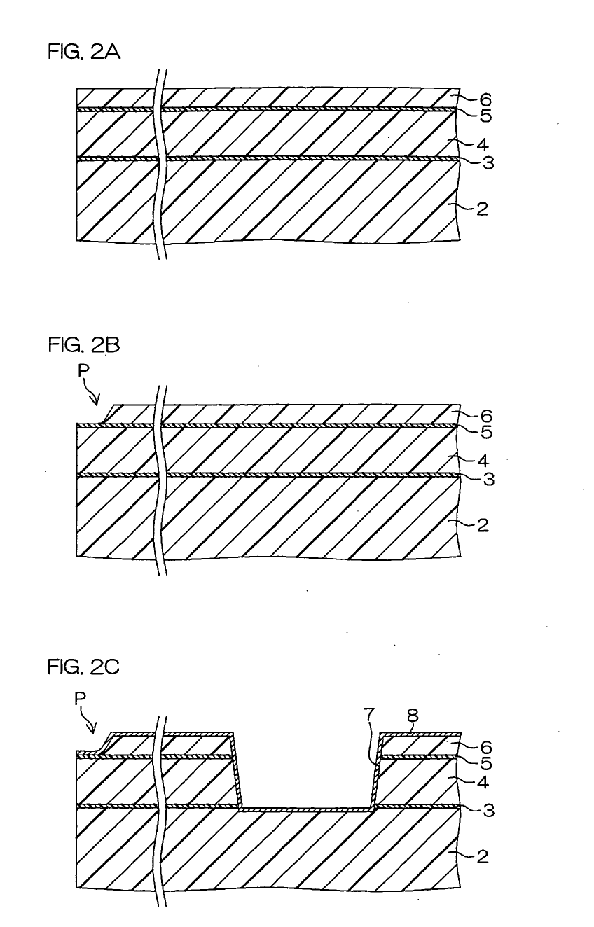

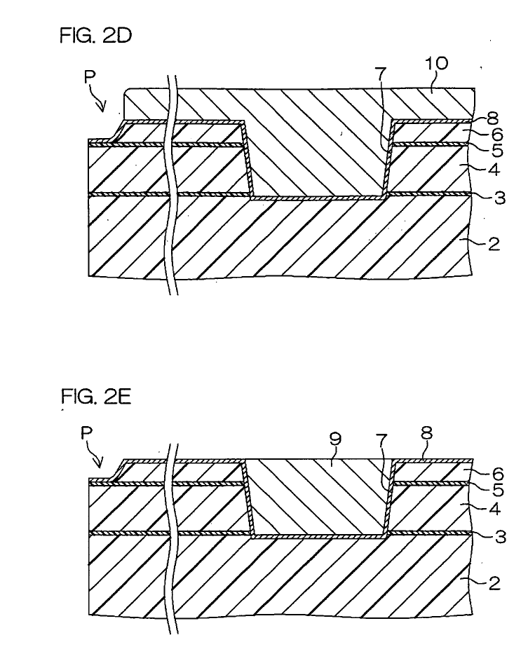

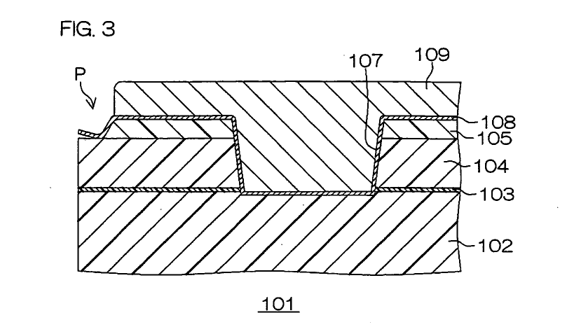

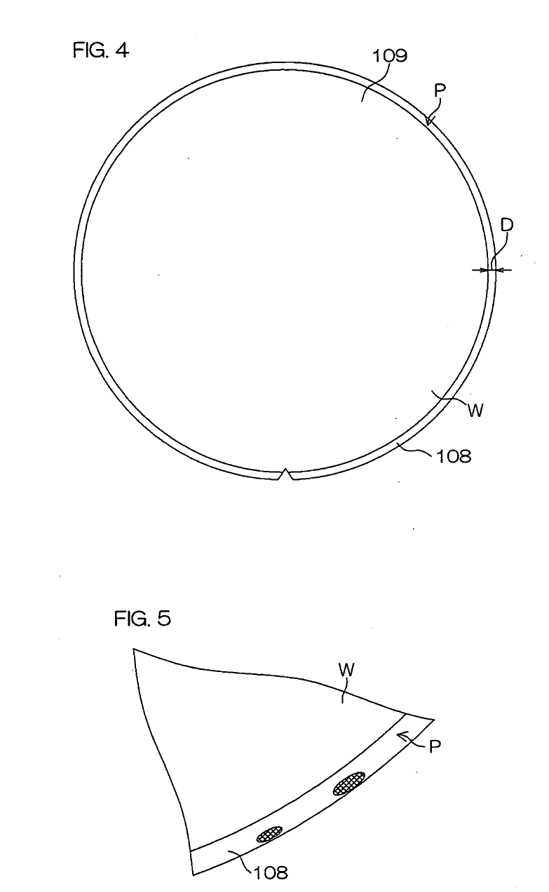

FIGS. 2A to 2E are schematic sectional views illustrating, in order of process, a method for manufacturing the semiconductor device.

The semiconductor device 1 is formed with the semiconductor substrate that makes up the base thereof being in a state of a wafer.

First, as shown in FIG. 2A, the interlayer insulating film 2, the etching stopper film 3, the low dielectric layer 4, the high dielectric layer 5, and the protective layer 6 are laminated on the wafer in that order from the wafer side.

Thereafter, rinsing of a rear surface of the wafer is performed. During rinsing, a rinsing liquid supplied to the rear surface of the wafer flows around to a peripheral edge portion of a top surface of the wafer, and at a peripheral edge portion (left end portion in FIGS. 2A to 2E) P of the wafer, a peripheral edge portion of the protective layer 6 is removed and a peripheral edge portion of the high dielectric layer 5 is exposed as shown in FIG. 2B.

Next, as shown in FIG. 2C, the wiring groove 7 is formed by digging in from the upper surface of the protective layer 6 to the interlayer insulating film 2. The barrier film 8 is formed, for example, by a sputtering on the protective layer 6 including the inner surface of the wiring groove 7 (entire surface of the wafer). At the peripheral edge portion P of the wafer, because the peripheral edge portion of the protective layer 6 is removed and the peripheral edge portion of the high dielectric layer 5 is exposed, the barrier film 8 contacts the exposed portion of the high dielectric layer 5.

Then, as shown in FIG. 2D, a plating layer 10 made of the material of the Cu wiring 9 is formed on the barrier film 8, for example, by an electrolytic plating. The plating layer 10 is formed to a thickness of completely filling the wiring groove 7. The plating layer 10 is removed from the peripheral edge portion P of the wafer. Remaining of the plating layer 10 at the peripheral edge portion P of the wafer after polishing of the plating layer 10 and the barrier film 8 by a CMP to be described next can thereby be prevented.

Next, the plating layer 10 is polished by the CMP. The polishing of the plating layer 10 is continued until a top surface of the barrier film 8 is exposed. Consequently, the Cu wiring 9 embedded in the wiring groove 7 via the barrier film 8 is obtained as shown in FIG. 2E.

Subsequently, a process of polishing the barrier film 8 by the CMP is performed. The polishing of the barrier film 8 is continued until the barrier film 8 is removed from the protective layer 6, a top surface of the protective layer 6 is exposed, and a top surface of the high dielectric layer 5 is exposed at the peripheral edge portion P of the wafer.

The semiconductor device 1 shown in FIG. 1 is thereafter obtained by the wafer being diced.

As described above, the high dielectric layer 5 made of the SiOC (3.2) is formed on the low dielectric layer 4 made of the SiOC (2.8). The high dielectric layer 5 is formed to a predetermined film thickness T. The protective layer 6 made of SiO₂ is formed on the high dielectric layer 5. That is, the high dielectric layer 5 is interposed between the low dielectric layer 4 and the protective layer 6. The wiring groove 7 dug in from the upper surface of the protective layer 6 to the interlayer insulating film 2 is formed in the low dielectric layer 4, the high dielectric layer 5 and the protective layer 6. The barrier film 8 made of Ta is formed on the bottom surface and the side surfaces of the wiring groove 7. The Cu wiring 9 made of Cu and completely filling the wiring groove 7 is formed on the barrier film 8.

The semiconductor device 1 is obtained by the wafer being diced after the Cu wiring 9 etc., have been formed on the wafer. Because the high dielectric layer 5 is interposed between the low dielectric layer 4 and the protective layer 6, even if the barrier film 8 is formed on an entire surface of the wafer after removal of the protective layer 6 from the peripheral edge portion P of the wafer, the barrier film 8 contacts the high dielectric layer 5, which exhibits high adhesion with the barrier film 8, at the peripheral edge portion P of the wafer. A peeled piece of the barrier film 8 thus does not form during polishing by the CMP for removing unnecessary portions of the plating layer 10 and the barrier film 8. Consequently, forming of a scratch on the top surface of the Cu wiring 9 due to a peeled piece of the barrier film 8 can be prevented.

The film thickness T of the high dielectric layer 5 is set in a range of not less than 5 nm and not more than 30 nm. By the film thickness T of the high dielectric layer 5 being not less than 5 nm, the high dielectric layer 5 can be formed to a uniform film thickness across an entirety of the wafer. Further, by the film thickness T being not more than 30 nm, increase in parasitic capacitance in the semiconductor device 1 can be suppressed.

Various modifications can be applied to the present embodiment.

For example, although the SiOC (3.2) was used as the material (high dielectric material) of the high dielectric layer 5, in a case where Ta is used as the material of the barrier film 8, it suffices that the SiOC that is the material of the high dielectric layer 5 has a dielectric constant of not less than 3. In this case, good adhesion can be exhibited between the high dielectric layer 5 made of the SiOC and the barrier film 8 made of Ta.

Further, although the low dielectric layer 4 and the high dielectric layer 5 are formed using the SiOCs that are the same type of materials that differ in dielectric constant, these may be formed instead from materials of different types. For example, an SiOC may be used as the material of the low dielectric layer 4, and an SiOF (silicon oxide with fluorine added) may be used as the material of the high dielectric layer 5. In this case, it suffices that the SiOF that is the material of the high dielectric layer 5 has a dielectric constant enabling exhibition of good adhesion with the barrier film 8, and that the SiOC that is the material (low dielectric material) of the low dielectric layer 4 has a dielectric constant lower than the SiOF that is the material of the high dielectric layer 5.

Further, SiC (silicon carbide), SiCO etc., can be cited as examples of the material of the high dielectric layer 5.

Further, although the Cu wiring 9 is made of Cu, it does not necessarily have to be made of only Cu and it may be formed of a metal material containing Cu as a main component.

While the present invention has been described in detail by way of the embodiments thereof, it should be understood that these embodiments are merely illustrative of the technical principles of the present invention but not limitative of the invention. The spirit and scope of the present invention are to be limited only by the appended claims.

This application corresponds to Japanese Patent Application No. 2008-3435 filed with the Japan Patent Office on Jan. 10, 2008, and Japanese Patent Application No. 2009-2808 filed therewith on Jan. 8, 2009, the disclosures of these applications are incorporated herein by reference.

What is claimed is:

1. A semiconductor device comprising:
a low dielectric layer made of a low dielectric material;
a high dielectric layer formed on the low dielectric layer and made of a high dielectric material having a higher dielectric constant than the low dielectric material;
a protective layer formed on the high dielectric layer and made of an insulating material differing from the low dielectric material and the high dielectric material;
a groove formed by digging in from an upper surface of the protective layer to the low dielectric layer;
a barrier film coated onto a bottom surface and side surfaces of the groove and made of a material having a barrier property with respect to diffusion of Cu; and
a wiring formed on the barrier film, made of a metal material having Cu as a main component, and completely filling the groove.

2. The semiconductor device according to claim 1, wherein
the high dielectric layer has a thickness of not less than 5 nm and not more than 30 nm.

3. The semiconductor device according to claim 1, wherein
Ta is used as the material of the barrier film,
an SiOC having a dielectric constant of 3.2 is used as the high dielectric material, and
an SiOC having a dielectric constant of 2.8 is used as the low dielectric material.
